(19) United States
(12) Patent Application Publication
(10) Pub. No.: US 2019/0322211 A1
(43) Pub. Date: Oct. 24, 2019

(54) ILLUMINATED DEVICE

(71) Applicant: SIGMA INTERNATIONAL, Livonia, MI (US)

(72) Inventors: Seunglye KIM, Troy, MI (US); Wonseok YANG, Rochester Hills, MI (US)

(21) Appl. No.: 16/473,797

(22) PCT Filed: Dec. 29, 2017
(86) PCT No.: PCT/US2017/068973

§ 371 Date: Jun. 26, 2019

Related U.S. Application Data
(60) Provisional application No. 62/440,881, filed on Dec. 30, 2016.

(51) Int. Cl. B60Q 3/64; B60Q 3/14; B60Q 3/283; B60Q 3/80; H05K 1/02

(52) U.S. Cl. CPC B60Q 3/64; B60Q 3/14; H05K 1/02; B60Q 3/80; B60Q 3/283

(57) ABSTRACT

An illustrative example device includes a light source and a housing including a shell that covers the light source. The shell comprises an at least partially transparent material. The shell has a first side facing the light source and a second side facing away from the light source. A first, light blocking layer covers at least part of the shell on at least one of the first side and the second side. The first layer includes at least one gap through which light from the light source is visible. A second, light permeable layer over the second side of the shell conceals at least part of the first layer and the at least one gap from view on the second side of the shell. The second layer has a first, consistent appearance when the light source is off and a second, partially illuminated appearance when the light source is on.

### CROSS-REFERENCE TO RELATED APPLICATION

The present disclosure is a national stage application of PCT/US2017/068973 filed Dec. 29, 2017, which claims priority to U.S. Provisional Patent Application No. 62/440881 filed on Dec. 30, 2016.

### BACKGROUND

There are a variety of devices that have lighting to provide a user information or to display a symbol for aesthetic purposes. One use of such devices is in automotive vehicles. Switches and buttons may be lighted to assist a driver reaching for them at night or to provide a visual look and feel inside the vehicle. In another example, the lights might be decorative, such as for displaying a logo on an airbag cover.

Known devices of this type may be painted, chrome plated or have a film over portions of the device that are not lit and a different appearance at the locations where a lighted effect is desired. For some situations it would be better or more desirable if the switches or buttons could have a uniform appearance at least when they are not lit. Another shortcoming of some known devices is that the lighting is inconsistent or non-uniform leaving some areas more dimly lit while others are so-called hot spots with a noticeably brighter appearance.

### SUMMARY

An illustrative example device includes a light source and a housing including a shell that covers the light source. The shell comprises an at least partially transparent material. The shell has a first side facing the light source and a second side facing away from the light source. A first, light blocking layer covers at least part of the shell on at least one of the first side and the second side. The first layer includes at least one gap through which light from the light source is visible. A second, light permeable layer over the second side of the shell conceals at least part of the first layer and the at least one gap from view on the second side of the shell. The second layer has a first, consistent appearance when the light source is off and a second, partially illuminated appearance when the light source is on.

In an example embodiment having one or more features of the device of the previous paragraph, the first layer and second layer comprise coatings applied to the shell.

In an example embodiment having one or more features of the device of any of the previous paragraphs, the gap provides an area on the shell that is free of the first layer and the area is covered by the second layer.

An example embodiment having one or more features of the device of any of the previous paragraphs includes a light guide that directs light from the light source toward the at least one gap.

In an example embodiment having one or more features of the device of any of the previous paragraphs, the light guide includes a multifaceted surface causing light to leave the light guide in a plurality of directions.

In an example embodiment having one or more features of the device of any of the previous paragraphs, the light source comprises is a light emitting diode (LED).

In an example embodiment having one or more features of the device of any of the previous paragraphs, the light guide comprises polycarbonate or polymathic methacrylate.

In an example embodiment having one or more features of the device of any of the previous paragraphs, the first side of the housing is at least partially white.

In an example embodiment having one or more features of the device of any of the previous paragraphs, the first side comprises a white coating over portions of the first side other than a location of the at least one gap.

In an example embodiment having one or more features of the device of any of the previous paragraphs, the housing forms a decorative portion of an airbag cover.

In an example embodiment having one or more features of the device of any of the previous paragraphs, the second layer has a metallic appearance.

In an example embodiment having one or more features of the device of any of the previous paragraphs, the second layer comprises a physical vapor deposition layer.

In an example embodiment having one or more features of the device of any of the previous paragraphs, the second layer comprises a single, continuous and uninterrupted layer.

In an example embodiment having one or more features of the device of any of the previous paragraphs, the first layer is on the first side of the shell and the second layer has a consistent thickness on the second side of the shell.

In an example embodiment having one or more features of the device of any of the previous paragraphs, the first layer is on the second side of the shell, the second layer has a first thickness over the first layer, and the second layer has a second, greater thickness over portions of the shell including the at least one gap.

In an example embodiment having one or more features of the device of any of the previous paragraphs, the at least one gap defines a decorative symbol that appears illuminated when the light source is on.

An illustrative example method of making a shell for a selectively illuminated device includes at least partially coating at least one side of a shell with a first, light blocking layer; removing part of the first layer to provide at least one gap through which light may pass; and at least partially coating the shell with a second, light permeable layer, the second layer concealing a portion of the shell including at least some of the first layer and the at least one gap, the second layer having a consistent appearance on an exterior of the second layer.

In an example embodiment having one or more features of the method of the previous paragraph, removing the part of the first layer comprises laser etching, laser patterning or laser engraving.

In an example embodiment having one or more features of the method of any of the previous paragraphs, the coating with the second layer comprises physical vapor deposition.

In an example embodiment having one or more features of the method of any of the previous paragraphs, the second layer comprises a single, continuous and uninterrupted layer.

Various features and advantages of at least one disclosed example embodiment will become apparent to those skilled in the art from the following detailed description. The drawings that accompany the detailed description can be briefly described as follows.

### BRIEF DESCRIPTION OF THE DRAWINGS

FIG. 1 illustrates selected portions of an interior of an automotive vehicle including devices designed according to an embodiment of this invention.

FIG. 2 illustrates an example embodiment of an illuminated device designed according to an embodiment of this invention.

FIG. 3 is a partially exploded view of the device of FIG. 2.

FIG. 4 is a cross-sectional illustration taken along section lines 4-4 in FIG. 2.

FIG. 5 is an expanded view of the portion of FIG. 4 encircled at 5.

FIG. 6 is a flowchart diagram summarizing an example manufacturing process.

FIG. 7 schematically illustrates a portion of an example manufacturing process.

### DETAILED DESCRIPTION

Devices designed according to an embodiment of this invention are useful for a variety of purposes, such as switches, dials, indicators, buttons or decoration within an automotive vehicle. Embodiments of this invention are superior to prior devices, in part, because they provide a uniform and visually pleasing appearance when the device is not illuminated and when lit provide consistent light intensity across the area that is illuminated.

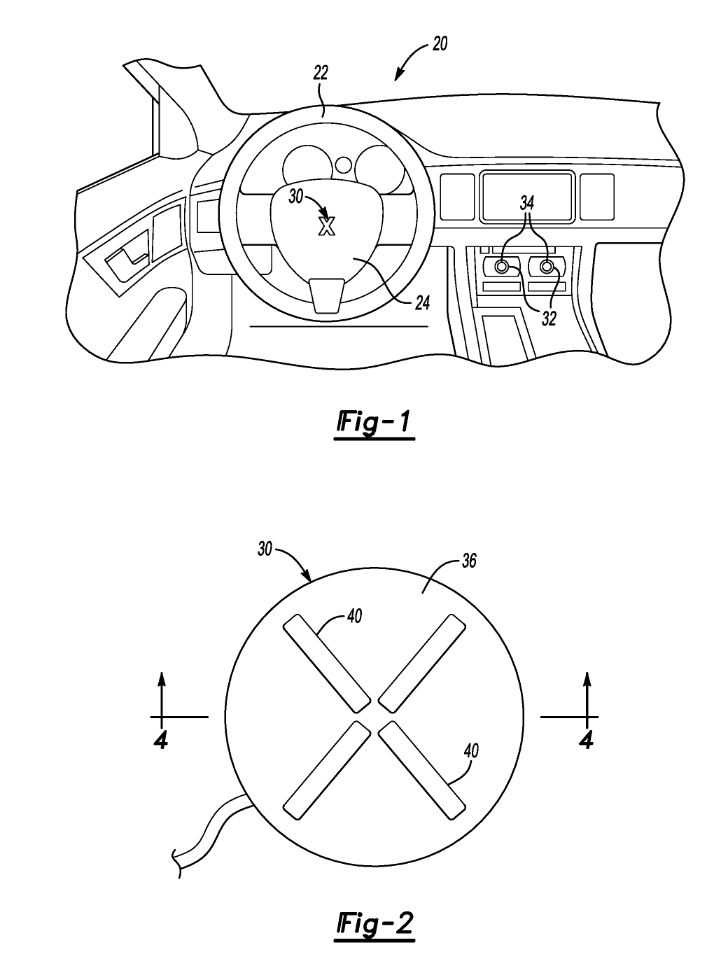

FIG. 1 shows portions of an automotive vehicle interior 20 including a steering wheel 22 and an airbag cover 24. In this example, an illuminated device 30 provides a decorative accent or emblem on the airbag cover 24. For discussion purposes, the device 30 includes visible features that appear like the letter X but other and more complex symbols are included in some embodiments.

The vehicle interior 20 also includes a variety of switches or controls 32 that comprise an illuminated device. In this example, round knobs 32 include selectively illuminated rings 34 that appear lit under selected conditions.

FIG. 2 shows an example device 30 that includes a shell 36 with raised portions 40 that establish the X shape of the visible symbol on the airbag cover 24. In this example, a fabric of the airbag cover 24 includes cut-outs through which the raised portions 40 protrude and are visible.

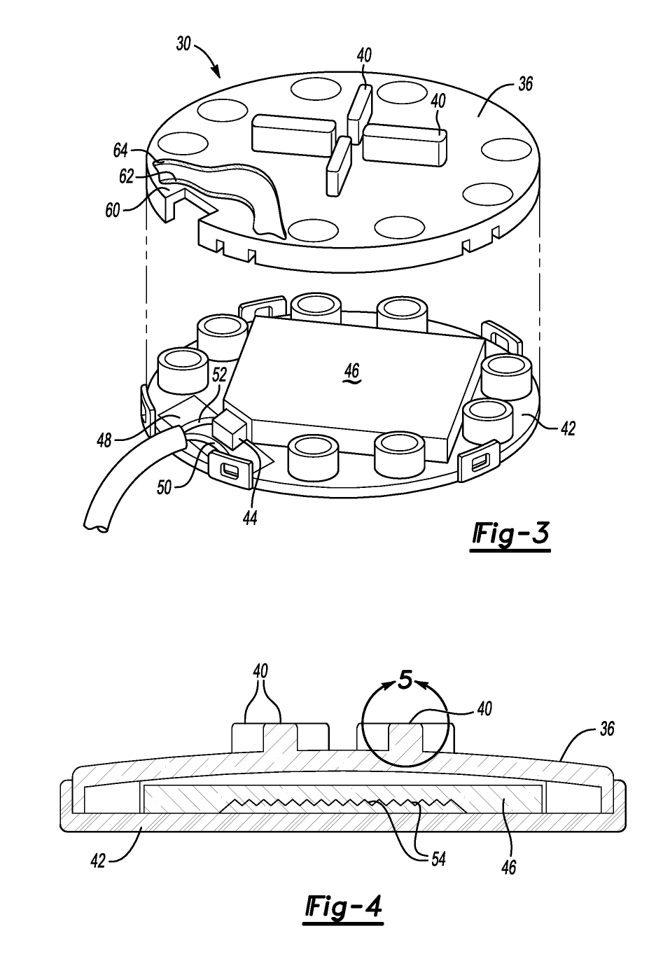

FIG. 3 is a partially exploded view of the device 30 showing the shell 36 removed from a base 42. A light source 44, such as a light emitting diode (LED) is supported on the base 42. A light guide 46 directs light from the light source 44 toward the raised portions 40 so that the X-shaped symbol appears illuminated when the light source 44 is turned on. This example includes a printed circuit board 48 supported on the base 42. Conductors 50 and 52 communicate control or operation signals and power to the light source 44 and the circuit board 48. A controller (not illustrated), for example, provides control signals to turn on the light source 44 when the symbol, emblem or pattern on the device 30 should appear lit up.

The light guide 46 in the illustrated example comprises a polycarbonate and polymathic methacrylate (PMMA) material. The light guide 46 in this embodiment has at least one multifaceted, irregular, or roughened surface 54, which is schematically shown near the bottom of FIG. 4. Light within the light guide 46 reflects off the various aspects or facets of the surface 54 and this results in an increase in the amount of light approaching the locations on the device 30 that will be illuminated to establish or display the illuminated symbol or indicator. In some embodiments the facets or irregularities in the surface 54 are arranged according to a predetermined design or pattern to control how light reflects within and emanates from the light guide 46.

Other embodiments includes at least some surface variation to spread light in various directions. Regardless of the type or form of the surface 54, the various directions of the reflected light provides a more uniformly illuminated appearance for the device 30 and makes the symbol or indicator on the device 30 more visible from various lines of sight. For example, the X-shaped symbol is visible when the device 30 is viewed from multiple, different angles relative to the exterior surface of the shell 36. This is an improvement over previous devices that were only visible from a viewing angle that is close to perpendicular to the surface of the lit symbol or indicator.

Another feature of the example device 30 is that an interiorly facing surface on the shell 36 is white to increase light reflection within the device 30, which results in better illumination of the symbol when the light source 44 is turned on. The illustrated shell 36 comprises a white acrylic material or a clear acrylic with white paint applied to at least some surfaces on the interiorly-facing side of the shell 36. An example shell material comprises polymethyl methacrylate (PMMA). In this example, the shell is generally clear or transparent and highly translucent to allow light emanating from the light guide 46 to be seen from outside the device 30 (e.g., from above in FIG. 4). In some embodiments at least a portion of the interior surface of the shell 36 that is not coincident with the raised portions 40 is painted white. A masking technique controls which portions of the interior surface are painted in some embodiments.

Referring to FIGS. 3 and 5, the shell 36 has a first side facing the light source 44 and a second side 60 that faces away from the light source 44. The shell 36 has a first, light-blocking layer 62 applied to at least one of the first or second sides. FIGS. 3 and 5 illustrate the first layer 62 on the second side 60. In some embodiments the configuration or geometry of the shell 36 may make coating the first, inner facing side more efficient while in others, like the illustrated example, coating the second side 60 with the first layer 62 provides better results.

A second layer 64 is applied over the second side 60. In this example, the second layer 64 is applied over the first layer 62. The second layer 64 is translucent and allows light from the light source 44 and the light guide 46 to pass through gaps 66 in the first layer 62. The configuration of the gaps 66 defines or establishes the shape of the illuminated symbol as the light-blocking first layer 62 blocks any light from passing through portions of the shell 36 that include the first layer 62.

In one example embodiment, the first layer 62 comprises black paint and the second layer 64 comprises a coating applied by physical vapor deposition (PVD). The second layer 64 provides a metallic appearance in this example. One feature of the illustrated embodiment is that the PVD second layer coating 64 is on the outwardly facing side of the shell 36 rather than being on an inwardly facing surface. In other devices that included a PVD coating, that coating was applied to the inner surface of the device. In the embodiment illustrated in FIG. 5, a clear coat layer 68 is applied over the PVD coating second layer 64 as a protective layer. The clear coat layer 68 in some embodiments resists ultraviolet (UV) radiation.

One feature of the exterior appearance of the device 30 is that the PVD second layer 64 appears continuous and consistent across the entire coated portion of the shell 36 where the second layer 64 conceals the first layer 62 and the gaps 66. When the light source 44 is off and the device 30 is not lit, the exterior of the device 30 has a uniform appearance established by the second layer 64. When the light source 44 is on, those portions of the shell that include the gaps 66 are illuminated as the PVD coating second layer 64 allows light to pass through. Those portions covered with the first layer 62, such as black paint, do not allow light to pass through.

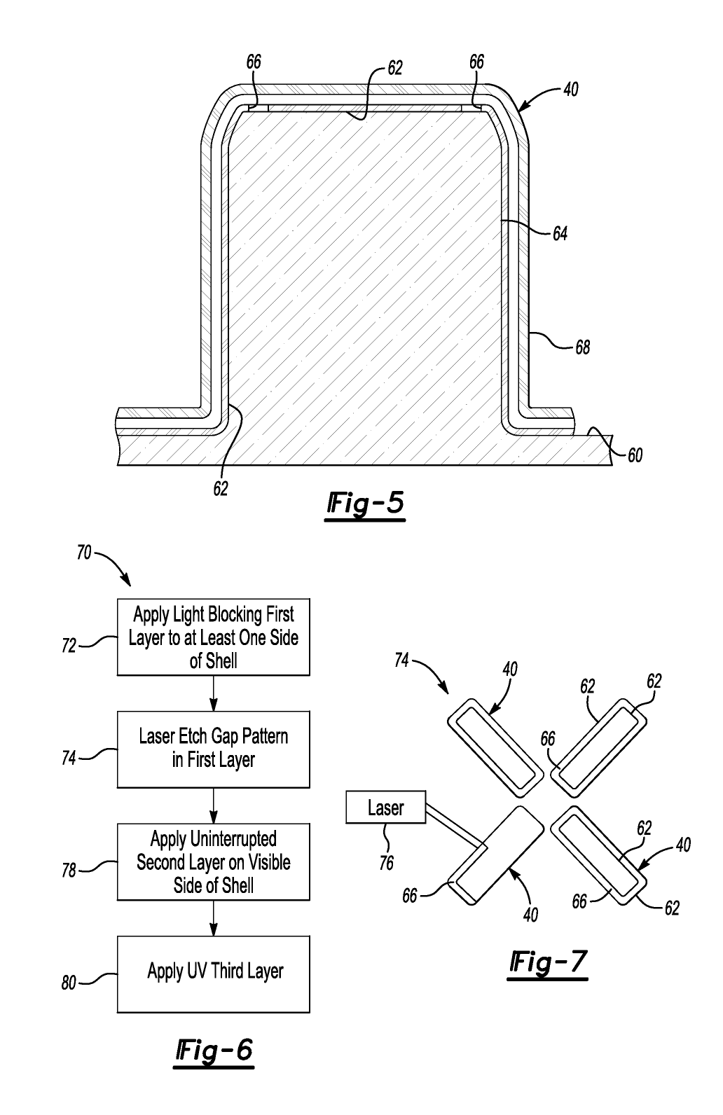

FIG. 6 includes a flow chart diagram 70 summarizing an example process of making a device and, in particular, a process of making the shell 36. At 72 the first light-blocking layer 62 is applied to at least one side of the shell 36. At 74, at least one gap 66 in the first layer is established. In this example, a pattern for the gap 66 is laser etched into the first layer 62. FIG. 7 schematically illustrates an example embodiment in which a laser 76 follows a prescribed pattern along the raised portions to remove some of the first layer 62 where the gap or gaps 66 are needed to establish the desired light pattern when the device 30 is illuminated. FIG. 7 shows three of four raised portions 40 with completed gaps 66 and the laser 76 performing the etching or laser patterning to establish a gap 66 around a fourth one of the raised portions 40. Other devices have different patterns and laser etching or laser engraving in such embodiments allows for establishing a desired illuminated symbol or emblem.

At 78 in FIG. 6, the second layer 64 is applied to the second side 60 of the shell 36. In this example, the second layer 64 is applied over the first layer 62 and the gaps 66. The second layer 64 in some such embodiments includes a first thickness or depth over the first layer 62 and a second, greater thickness or depth over the gaps 66. A difference between the first and second thickness is approximately equal to a thickness of the first layer 62. Including different thicknesses of the second layer 64 allows for the finish surface of the device 30 to have a continuous, uninterrupted appearance at least when the light source 44 is off. In some embodiments the second layer 64 has a uniform thickness and a consistent, uninterrupted appearance. In either type of embodiment, the PVD second layer 64 is consistent and the locations of the gaps 66 are not visible to an individual looking at the outer surface of the device 30. When the light source 44 is off, the exterior surface of the device 30 appears the same across the visible exterior surface regardless of the position or location of the first layer 62 and the gaps 66. This provides significant aesthetic advantages as the entire device can have a finished and consistent appearance, which differs from previous devices that have a different appearance on the locations that may be lit compared to those that do not.

Having the entire outer surface of the shell 36 (or at least those portions that are visible in a finished product) coated with the PVD second layer 64 gives the device 30 a uniform, metallic appearance when no light is provided by the light source 44 for illuminating the symbol. When lit, the portions of the surface that are coated with the first, light-blocking layer 62 appear to have the same metallic appearance as when the device is not illuminated while the portions including the gap or gaps 66 corresponding to the symbol or indicator are illuminated.

At 80 a protective clear coat or UV resistant third layer is applied over the second layer 64. In this example, the third layer 68 does not alter the consistent or uninterrupted appearance of the second layer 64 but may enhance its appearance such as by increasing the shine of the finished product.

The example embodiment and others having similar features provide a pleasing, consistent look and feel for a device 30 including a selectively illuminated pattern, symbol or emblem. When the device 30 is not lit the outer surface has an even, consistent appearance. The second layer 64 allows light from the light source 44 inside the device 30 to radiate out through areas including a gap or gaps 66 corresponding to the symbol or indicator with relatively consistent brightness across a wide range of perspectives. The device 30 according to the illustrated embodiment minimizes or eliminates dimly lit areas or relatively brighter hot spots on the illuminated pattern.

The preceding description is illustrative rather than limiting in nature. Variations and modification to the disclosed example embodiment may become apparent to those skilled in the art that do not necessarily depart from the essence of this invention. For that reason, the following claims should be studied to determine the scope of legal protection over this invention.

We claim:

1. A device comprising:
a light source; and
a housing including:
a shell that covers the light source, the shell comprising an at least partially transparent material, the shell having a first side facing the light source and a second side facing away from the light source;
a first, light blocking layer covering at least part of the shell on at least one of the first side and the second side, the first layer including at least one gap through which light from the light source is visible;
a second, light permeable layer over the second side of the shell, the second layer concealing at least part of the first layer and the at least one gap from view on the second side of the shell, the second layer having a first, consistent appearance when the light source is off, the second layer having a second, partially illuminated appearance when the light source is on.

2. The device of claim 1, wherein the first layer and second layer comprise coatings applied to the shell.

3. The device of claim 2, wherein
the gap provides an area on the shell that is free of the first layer; and
the area is covered by the second layer.

4. The device of claim 1, comprising
a light guide that directs light from the light source toward the at least one gap.

5. The device of claim 4, wherein the light guide includes a multifaceted surface causing light to leave the light guide in a plurality of directions.

6. The device of claim 5, wherein the light source comprises is a light emitting diode (LED).

7. The device of claim 5, wherein the light guide comprises polycarbonate or polymathic methacrylate.

8. The device of claim 1, wherein the first side of the housing is at least partially white.

9. The device of claim 8, wherein the first side comprises a white coating over portions of the first side other than a location of the at least one gap.

10. The device of claim 1, wherein the housing forms a decorative portion of an airbag cover.

11. The device of claim 1, wherein the second layer has a metallic appearance.

12. The device of claim 1, wherein the second layer comprises a physical vapor deposition layer.

13. The device of claim 1, wherein the second layer comprises a single, continuous and uninterrupted layer.

14. The device of claim 13, wherein
the first layer is on the first side of the shell; and
the second layer has a consistent thickness on the second side of the shell.

15. The device of claim 13, wherein
the first layer is on the second side of the shell;
the second layer has a first thickness over the first layer; and
the second layer has a second, greater thickness over portions of the shell including the at least one gap.

16. The device of claim 1, wherein the at least one gap defines a decorative symbol that appears illuminated when the light source is on.

17. A method of making a shell for a selectively illuminated device, the method comprising:
at least partially coating at least one side of a shell with a first, light blocking layer;
removing part of the first layer to provide at least one gap through which light may pass;
at least partially coating the shell with a second, light permeable layer, the second layer concealing a portion of the shell including at least some of the first layer and the at least one gap, the second layer having a consistent appearance on an exterior of the second layer.

18. The method of claim 17, wherein removing the part of the first layer comprises laser etching, laser patterning or laser engraving.

19. The method of claim 17, wherein the coating with the second layer comprises physical vapor deposition.

20. The method of claim 17, wherein the second layer comprises a single, continuous and uninterrupted layer.
